(19) United States
(12) Patent Application Publication
(10) Pub. No.: US 2010/0059771 A1
(43) Pub. Date: Mar. 11, 2010

(54) MULTI-LAYER LED PHOSPHORS

(76) Inventors: Chris Lowery, Sunnyvale, CA (US); Alex Shaikevitch, Sunnyvale, CA (US)

Correspondence Address: Haynes and Boone, LLP;IP Section, 2323 Victory Avenue, SUITE 700, Dallas, TX, 75219, US

(21) Appl. No.: 12/208,077

(22) Filed: Sep. 10, 2008

(51) Int. Cl. H01L 33/00

(52) U.S. Cl. 257/98; 257/E33.061

(57) ABSTRACT

An LED assembly can have a plurality of different types of phosphors that are separated from one another in a manner that substantially mitigates the cannibalization of light emitted by at least one of the types of phosphors. By mitigating the cannibalization of light, brighter and more efficient white light LED assemblies can be provided. Such LED assemblies can be suitable for use in such applications as flashlights, displays, and area lighting.

### TECHNICAL FIELD

The present invention relates generally to light emitting diodes (LEDs). The present invention relates more particularly to methods and systems for changing the color of light emitted from an LED die by using a plurality of layers of phosphors.

### BACKGROUND

Light emitting diodes (LEDs) are well known. LEDs are semiconductor devices that emit light when the p-n junction thereof is forward biased. LEDs are commonly used as indicator lights on electronic devices. For example, the red power indicator on consumer electronic devices is often an LED.

The use of LEDs in other applications is increasing. For example, LEDs are being used in applications such as flashlights, displays, and area lighting. LEDs can generally provide light at a lower cost than other illumination devices, such as incandescent lights and fluorescent lights.

In some applications it is desirable to provide white light. For example, white light is generally preferred for flashlights and area illumination. White light is a mixture of other colors, e.g., red, blue, and green, of light. However, LEDs commonly provide blue light. Therefor, it is desirable to provide LEDs that emit white light.

### BRIEF SUMMARY

Methods and systems are disclosed herein to mitigate the undesirable cannibalization of light from one phosphor by another phosphor. For example, an LED assembly can be provided wherein such cannibalization is substantially mitigated.

In accordance with an example of an embodiment, an LED assembly can comprise a plurality of different types of phosphors that are separated from one another in a manner that substantially mitigates cannibalization of light emitted by at least one of the types of phosphors.

In accordance with an example of an embodiment, a phosphor layer for an LED assembly can comprise a plurality of different types of phosphors. The phosphors can define adjacent dots that are configured so as to substantially inhibit phosphor absorption/emission band interaction.

In accordance with an example of an embodiment, an LED assembly can comprise an LED die, a first layer comprising a first phosphor, and a second layer comprising a second phosphor. The first phosphor and the second phosphor can receive light from the die. The first phosphor and the second phosphor can each emit a different color of light with respect to one another. The first phosphor and the second phosphor can be arranged such that the absorption of light by one that was emitted by the other is substantially mitigated.

In accordance with an example of an embodiment, an illumination assembly can comprise a source of light, a first phosphor layer comprising a first phosphor that is configured to change a color of light from the source to a first color and a second phosphor layer comprising a second phosphor that configured to change a color of light from the source to a second color. The first and second phosphors can be configured such that light emitted by one is not substantially absorbed by the other.

In accordance with an example of an embodiment a method for modifying the color of light can comprise providing the light to a plurality of different types of phosphors. The phosphors can be separated from one another in a manner that substantially mitigates cannibalization of light emitted by at least one of the types of phosphors.

In accordance with an example of an embodiment a method for modifying the color of light can comprise depositing a plurality of different types of phosphors as adjacent dots. The dots can be positioned such that they substantially inhibit undesirable phosphor absorption/emission band interaction.

By mitigating the cannibalization of light, brighter and more efficient LED assemblies can be provided. The LED assemblies can provide white light or non-white light. Such LED assemblies can be suitable for use in such applications as flashlights, displays, and area lighting.

This invention will be more fully understood in conjunction with the following detailed description taken together with the following drawings.

### BRIEF DESCRIPTION OF THE DRAWINGS

FIG. 1 is a semi-schematic cross-sectional side view showing two phosphor layers of a light emitting diode (LED) assembly, wherein two different types of phosphors are separated from one another in a manner that substantially mitigates cannibalization of light emitted by at least one of the types of phosphors according to an example of an embodiment;

FIG. 2 is a semi-schematic top view corresponding to the cross-sectional view of FIG. 1, wherein the phosphors are configured as stripes across the phosphor layers, according to an example of an embodiment;

FIG. 3 is a semi-schematic top view corresponding to the cross-sectional view of FIG. 1, wherein the phosphors are configured to form a checkerboard pattern upon the phosphor layers, according to an example of an embodiment;

FIG. 4 is a semi-schematic cross-sectional side view showing two phosphor layers having a clear layer therebetween and further showing the use of vias for allowing a portion of the light from an LED die to leak past the phosphors, according to an example of an embodiment;

FIG. 5 is a semi-schematic cross-sectional side view showing two phosphor layers and further showing the use of vias for allowing a portion of the light from an LED die to leak past the phosphors, according to an example of an embodiment;

FIG. 6 is a semi-schematic top view corresponding to the cross-sectional views of FIGS. 4 and 5, where the phosphors are configured as stripes across the phosphor layers, according to an example of an embodiment;

FIG. 7 is a semi-schematic top view corresponding to the cross-sectional views of FIGS. 4 and 5, where the phosphors are configured to form a checkerboard-like pattern upon the phosphor layers, according to an example of an embodiment;

FIG. 8 is a semi-schematic cross-sectional view of an LED assembly showing an LED die and a plurality of phosphor layers, according to an example of an embodiment;

FIG. 9 is a block diagram showing the cannibalization of light from one phosphor by an overlapping other phosphor, according to contemporary practice; and

FIG. 10 is a block diagram showing how non-overlapping phosphors mitigate cannibalization of light, according to an example of an embodiment.

Embodiments of the present invention and their advantages are best understood by referring to the detailed description that follows. It should be appreciated that like reference numerals are used to identify like elements illustrated in one or more of the figures.

### DETAILED DESCRIPTION

Methods and systems for making LED assemblies that produce a desired color of light, such as substantially white light, are disclosed. According to an example of an embodiment, LEDs that produce substantially white light can comprise multilayer phosphor films. The multilayer films change the color of light emitted by LEDs.

According to an example of an embodiment, an LED assembly can comprise a plurality of different types of phosphors. Any desired number of types of phosphors can be used. The phosphors can be separated from one another in a manner that substantially mitigates the undesirable cannibalization of the light emitted by at least one of the types of phosphors.

According to an example of an embodiment, a phosphor layer for an LED assembly can comprise a plurality of different types of phosphors that are configured such that the phosphors define adjacent dots. The dots can be configured so as to substantially inhibit phosphor absorption/emission band interaction.

According to an example of an embodiment, an LED assembly can comprise an LED die, a first layer, and a second layer. The first layer can comprise a first phosphor. The second layer can comprise a second phosphor. The first phosphor and the second phosphor can receive light from the LED die. The first phosphor and the second phosphor can each emit a different color of light with respect to one another. The first phosphor and the second phosphor can be arranged such that the absorption of light by one that was emitted by the other is substantially mitigated.

The first and second phosphors can be configured such that they do not substantially overlap one another. In this manner, light emitted by one phosphor is less likely to be absorbed by the other phosphor. For example, two or more different phosphors can be configured so as to define a checkerboard pattern. As a further example, two or more phosphors can be configured so as to define a striped pattern.

A plurality of vias can be configured so as to facilitate leakage of light from the LED die past the first phosphor and the second phosphor. The vias can be generally round, square, rectangular, triangular, oval or any other shape or combination of shapes.

A clear layer can be disposed between the first and second layers. The clear layer can facilitate and/or enhance adhesion of the first and second layers. Alternatively, the intermediate layer can be non-clear.

A clear layer can cover the first and second layers. A plurality of vias can be formed through the first layer, the second layer, and the intermediate layer. The vias can facilitate the leakage of light from the LED die without the leaked light being absorbed and re-emitted by a phosphor. The vias can be holes or voids. The vias can be clear material. The vias can allow light of a desired color, e.g., blue light, to be transmitted therethrough.

A Bragg mirror can be formed upon one or more of the clear layers. For example, a Bragg mirror can be formed upon a surface of the clear layer or layers that is closest to the LED die. The Bragg mirror can reflected wavelengths of light that are not desired to be emitted by the LED assembly such that these wavelengths are not emitted by the LED assembly. The Bragg mirror can reflected wavelengths of light that are desired to be emitted by the LED assembly such that these wavelengths are emitted by the LED assembly.

According to an example of an embodiment, an illumination assembly can comprise a source of light, a first phosphor layer, and a second phosphor layer. The first phosphor layer can comprise a first phosphor that is configured to change a color of light from the LED die to a first color. Similarly, the second phosphor layer can comprise a second phosphor that configured to change a color of light from the LED die to a second color. The first and second phosphors can be configured such that light emitted by one is not substantially absorbed or cannibalized by the other.

According to an example of an embodiment, a method for modifying the color of light can comprise providing the light to a plurality of different types of phosphors. The different types of phosphors can be separated from one another in a manner that substantially mitigates cannibalization of light emitted by at least one of the types of phosphors.

According to an example of an embodiment, a method for modifying the color of light can comprise depositing a plurality of different types of phosphors as adjacent dots. The dots can be configured such that their position substantially inhibits phosphor absorption/emission band interaction. For example, the dots can be positioned such that they do not substantially overlap one another.

One or more vias can be formed so as to facilitate the desirable leakage of light past the phosphors. This leaked light can contribute to the perceived color of the light emitted by the LED assembly. For example, blue light from an LED die can be allowed to leak though vias, past the phosphors, such that the blue light combines with red light and green light from the phosphors to form what is perceive as white light.

As those skilled in the art will appreciate, films or layers containing phosphors can be used to make white light LED assemblies. Phosphors can be placed in the light path of a blue LED die so as to change the color of light emitted by the LED die. Thus, LED dice having an emission wavelength in the range of 385 nm to 465 nm, for example, can be used to produce white light.

More particularly, a single phosphor that emits yellow light can be used with an LED die that emits blue light so as to produce white light. Some of the blue light is permitted to leak past the phosphor. This leaked blue light, typically in the range of 455 nm to 465 nm, combines with the yellow light, such as in the 560 nm range, to create light that is perceived as substantially white light.

Since the spectra of such LEDs is deficient in wavelengths that are present in natural sunlight, especially the longer wavelengths which we perceive as orange or red, the emitted white light produced by the combination of blue light from the LED and yellow from a phosphor appears to be somewhat bluish in color. This type of device is technically defined as having a high color temperature and a low color rendering index.

Some LEDs produce ultraviolet light, typically having a wavelength of approximately 420 nm. LEDs that produce ultraviolet light must currently use two or more phosphors to produce what appears to be white light to the human eye. This is necessary because such ultraviolet light LEDs lack the blue emission that leaks past the phosphor layer as is the case with blue LEDs.

Ultraviolet white light LEDs will typically have a mixture of the required phosphors in prescribed proportions. The phosphors can be dispersed in a carrier resin. For example, the carrier resin can be a silicone resin. Silicone resins are much less susceptible to structure damage due to high intensity, short wavelength light, as compared to other resins. As those skilled in the art will appreciate, such structure damage causes yellowing of the resin and this absorbs some of the useful light, thus reducing overall efficiency.

In both ultraviolet (UV) and blue excited LED's, mixing phosphors together and irradiating them to create a complementary color spectrum is not efficient, since the emission wavelength of one phosphor may overlap into the absorption band of another. Thus, light from one phosphor of a desired color can be undesirably absorbed by another phosphor. This cannibalization of emission spectra greatly reduces the efficiency of the device.

One or more embodiments can be used with blue light LEDs. One or more embodiments can be used with UV LEDs. Indeed embodiments can be used to change the color of light from any desire LED devices, as well as to change the color of light from non-LED devices.

Such cannibalization can be mitigated by the careful choice of phosphors, but this may undesirably limit the type of devices which can be constructed. As such, it is desirable to provide another method for mitigating such cannibalization.

According to an example of an embodiment, the separation of the phosphors can be used to ensure that substantially full conversion in one color is more efficiently accomplished before that color can be absorbed into a second phosphor. In this manner, undesirable cannibalization of light is substantially mitigated.

According to an example of an embodiment, phosphors may be deposited as adjacent dots of a predetermine size and at a predetermined location. This can be done in a manner that substantially inhibits phosphor absorption/emission band interaction and the consequent cannibalization of emissions.

According to an example of an embodiment, phosphors are separated into a plurality of layers or dots. For those examples of embodiments where the phosphors are separated into a plurality of layers, a clear layer can be formed between adjacent phosphor layers. This clear layer can function as an adhesion layer between the phosphor layers. The clear layer can be an efficient light transmission layer.

The clear layer can be enhanced by creating a Bragg mirror upon the surface thereof that is closest to the LED. Such a mirror can be referred to as a distributed Bragg reflector (DBR). Such a device can be constructed so as to define a one way mirror. That is, the DBR can allow wavelengths shorter than a predetermined wavelength to pass through it and for longer wavelengths to be reflected. Using such a mirror, emissions from a phosphor are inhibited from returning towards the LED and being wasted. Thus, the efficiency of the LED can be enhanced.

According to an example of an embodiment, phosphors and/or layers of phosphors can be configured so as to mitigate the undesirable cannibalization of light. As mentioned above, the absorption and emission bands of the phosphors can overlap. The phosphor with the shortest wavelength emission band can be formed upon the layer that is closest to the LED, followed by a DBR, then the next longest wavelength phosphor, and so on.

These layers can be formed by using sheet casting of the individual materials, followed by B-stage curing. The B-stage, or partial curing of the layer, ensures the adhesion of the subsequent layer. It is also possible to create these layers using screen printing or stenciling of the layers, with partial curing or B-staging the layers.

Furthermore, these fully cured layers can be cut into shapes and pre-tested. These pre-tested pieces can then be categorized into types which may produce color temperatures and color rendering indexes which are required.

This substantially reduces manufacturing waste, since only devices which are required are produced. The yield of desirable devices can be much higher than if all the pieces were made into devices. This reduces the cost of desirable devices.

The pre-testing can be accomplished by subjecting each piece to a known blue irradiation and measuring the phosphor emission using standard equipment. If the pieces are distributed in a known array, in a known location, then automatic equipment can store the data for each piece and retrieve that piece as required.

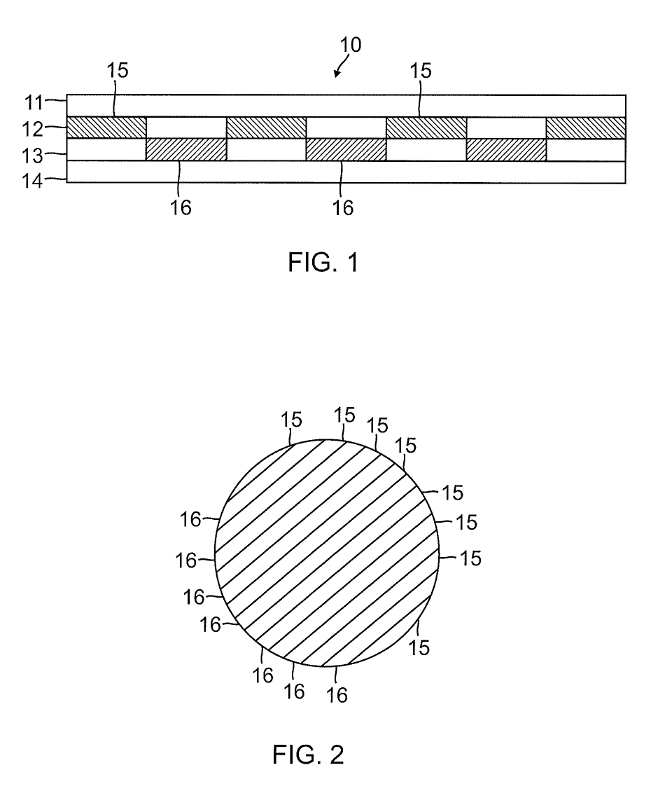

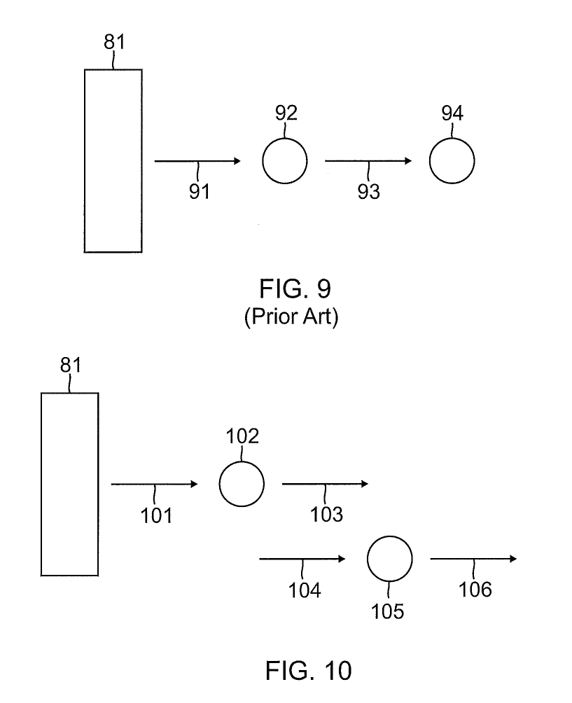

FIG. 1 is a semi-schematic cross-sectional side view showing a phosphor layer assembly 10, according to an example of an embodiment. First phosphor layer 12 and second phosphor layer 13 cooperate so as to change the color of light emitted by an LED die while mitigating undesirable cannibalism of light emitted from one or more of the phosphors. The cannibalization of light is shown in FIG. 9 and discussed in further detail below. Mitigation of such cannibalization is shown in FIG. 10 and discussed in further detail below.

First phosphor layer 12 can contain a first type of phosphor 15. Second phosphor layer 13 can contain a second type of phosphor 16. The first type of phosphor 15 and the second type of phosphor 16 can be separated from one another in a manner that substantially mitigates cannibalization of light emitted by at least one of the two types of phosphors. For example, the first type of phosphor 15 and the second type of phosphor can be positioned such that they do not substantially overlap one another.

Clear layer 11 and clear layer 14 can cover the top and bottom, respectively, of the phosphor layer assembly 10. Such clear layers 11, 14 can protect the first phosphor layer 12 and the second 13 phosphor layer 13 so as to facilitate handling and assembly thereof.

Within a layer (such as first phosphor layer 12 and/or second phosphor layer 13), the phosphors of a given type can be separated from one another by a clear material. Thus, each layer can comprise alternating stripes, squares, dots or other shapes of phosphor and clear material.

Referring now to FIG. 2, the first type of phosphor 15 and the second type of phosphor 16 of FIG. 1 can define a plurality of stripes, for example, when view from above. Stripes of alternating first type of phosphor 15 and second type of phosphor 16 can thus define a pattern that mitigates cannibalization of light emitted by at least one of the two types of phosphors. Such stripes can be formed so that they do not substantially overlap one another.

Within a layer, the stripes of phosphor can be separated from one another by a clear material. Thus, each layer can comprise alternating stripes of phosphor and clear material. The clear material can allow light from the LED die and/or light from phosphors of other layers to pass therethrough.

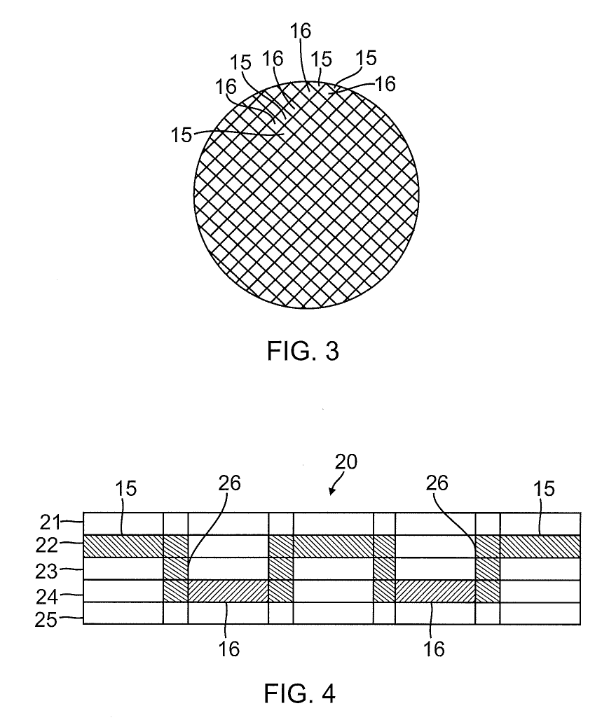

Referring now to FIG. 3, the first type of phosphor 15 and the second type of phosphor 16 can define a plurality of rectangles or squares, such as in a generally checkerboard-like pattern, for example, when viewed from above. Squares of alternating first type of phosphor 15 and second type of phosphor 16 can thus define a pattern that mitigates cannibalization of light emitted by at least one of the two types of phosphors. Such squares can be formed so that they do not substantially overlap one another.

Within a layer, the squares of phosphor can be separated from one another by a clear material. Thus, each layer can comprise alternating squares of phosphor and clear material.

Regardless of the particular configuration (such as stripes or squares), the first type of phosphor 15 can comprise one or more phosphors that produce red light, for example, when illuminated by light from the LED die. The second type of phosphor 16 can comprise one or more phosphors that produce green light, for example, when illuminated by the LED die. The area ratio between the first type of phosphor 15 and the second type of phosphor 16, as well as the concentrations of the first type of phosphor 15 and the second type of phosphor 16 in each layer, can determine the color temperature of the LED assembly.

FIG. 4 is a semi-schematic cross-sectional side view showing a phosphor layer assembly 20, according to an example of an embodiment. First phosphor layer 22, and second phosphor layer 24 cooperate so as to change the color of light emitted by an LED die while mitigating undesirable cannibalism of light emitted from one or more of the phosphors. A clear layer 23 can separate first phosphor layer 22 and second phosphor layer 24.

First phosphor layer 22 can contain a first type of phosphor 15. Second phosphor layer 24 can contain a second type of phosphor 16. The first type of phosphor 15 and the second type of phosphor 16 can be separated from one another in a manner that substantially mitigates cannibalization of light emitted by at least one of the two types of phosphors.

The clear layer 23, as well as the two phosphor layers 22 and 24, can comprise vias that allow light, such as blue light from the LED die, to pass through the phosphor layer assembly 20 without being absorbed by phosphors. Vias 26 can extend through the first phosphor layer 22, the clear layer 23, and the second phosphor layer 24. Thus, light for an LED die can leak through the phosphor layer assembly 20 without being changed in color. In this manner, red, green, and blue light can be provided by the LED assembly. This combination of red, green, and blue light can be perceived as substantially white light.

Clear layer 21 and clear layer 24 can cover the top and bottom, respectively, of the phosphor layer assembly 20. Such clear layers can protect the first phosphor layer 22 and the second 24 phosphor layer 13 so as to facilitate handling and assembly thereof.

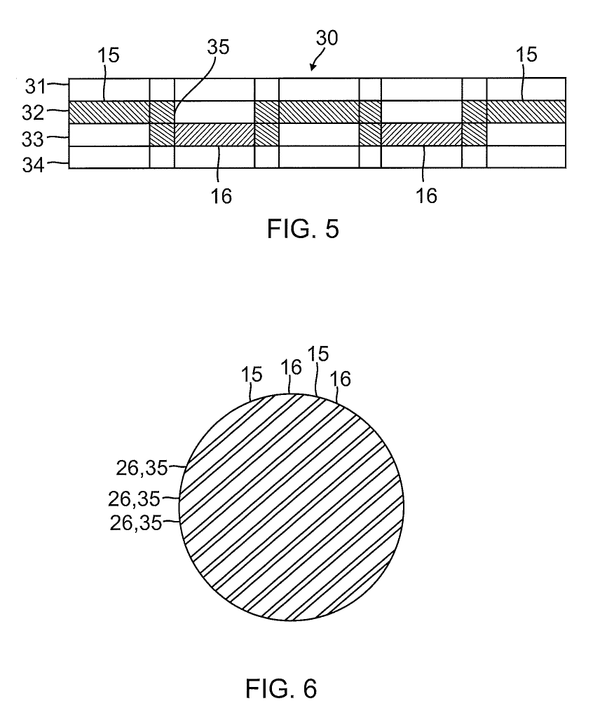

FIG. 5 is a semi-schematic cross-sectional side view showing a phosphor layer assembly 30, according to an example of an embodiment. First phosphor layer 32, and second phosphor layer 33 cooperate so as to change the color of light emitted by an LED die while mitigating undesirable cannibalism of light emitted from one or more of the phosphors.

No intermediate clear layer is used according to this embodiment. Vias 35 can be formed in the first phosphor layer 32 and the second phosphor layer 33 so as to facilitate the leakage of blue light from the LED die through the phosphor layer assembly.

First phosphor layer 22 can contain a first type of phosphor 15. Second phosphor layer 24 can contain a second type of phosphor 16. The first type of phosphor 15 and the second type of phosphor 16 can be separated from one another in a manner that substantially mitigates cannibalization of light emitted by at least one of the two types of phosphors.

The via layer 23 can comprise vias that allow light, such as blue light from the LED die, to pass through the phosphor layer assembly without being absorbed by phosphors. In this manner, red, green, and blue light can be provided by the LED assembly. This combination of red, green, and blue light can be perceived as substantially white light.

Clear layer 31 and clear layer 34 can cover the top and bottom, respectively, of the phosphor layer assembly 20. Such clear layers can protect the first phosphor layer 32 and the second phosphor layer 33 so as to facilitate handling and assembly thereof.

Within a layer, the phosphors can be separated from one another by a clear material. Thus, each layer can comprise alternating stripes or squares of phosphor and clear material.

Referring now to FIG. 6, the first type of phosphor 15 and the second type of phosphor 16 of FIGS. 4 and 5 can define a plurality of stripes, for example, when viewed from above. Stripes of alternating first type of phosphor 15 and second type of phosphor 16 can thus define a pattern that mitigates cannibalization of light emitted by at least one of the two types of phosphors.

The vias 26, 35 can be formed as trenches. The vias 26, 35 can thus define stripes that separate the stripes defined by the first type of phosphor 15 and second type of phosphor 16.

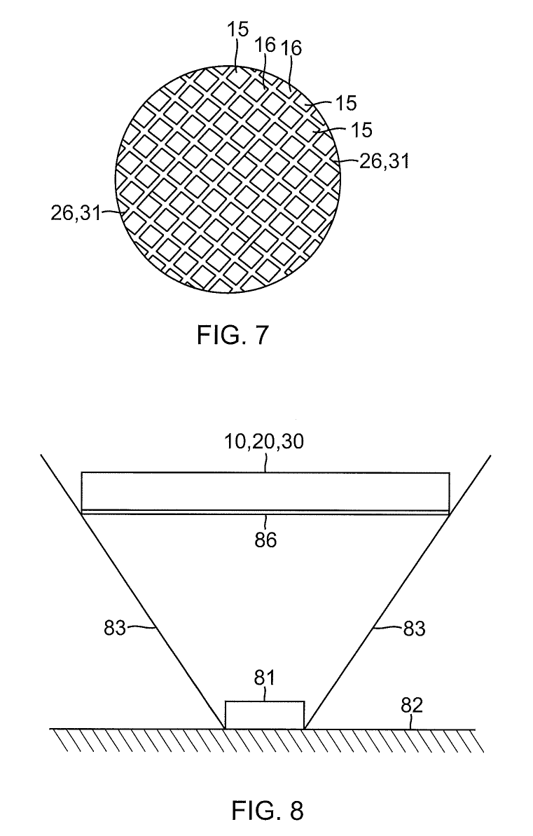

Referring now to FIG. 7, the first type of phosphor 15 and the second type of phosphor 16 can define a plurality of rectangles or squares, such as in a generally checkerboard pattern, for example, when viewed from above. Squares of alternating first type of phosphor 15 and second type of phosphor 16 can thus define a pattern that mitigates cannibalization of light emitted by at least one of the two types of phosphors.

Within a layer, the squares of phosphor can be separated from one another by a clear material. Thus, each layer can comprise alternating squares of phosphor and clear material.

The first type of phosphor 15 can comprise one or more phosphors that produce red light, for example, when illuminated by the LED die. The second type of phosphor 16 can comprise one or more phosphors that produce green light, for example, when illuminated by the LED die. The area ratio between the first type of phosphor 15 and the second type of phosphor 16, as well as the concentrations of the first type of phosphor 15 and the second type of phosphor 16 in each layer, can determine the color temperature of the LED assembly.

The vias 26, 35 can form a pattern of crisscrossing trenches when view from the top. Alternatively, the vias 26, 35 can be round, square, rectangular, or any other desired shape. A via can be any hole, opening, layer, material, or structure that allows light to pass therethough.

When vias 26, 35 are used, blue light from a blue LED die can be transmitted through the phosphor layer 20, 30 without being absorbed and re-emitted by phosphors. Thus, the blue light which passes through the vias 26, 35 can combine with other light from the LED die, such as light that has been absorbed and re-emitted by phosphors. Thus, phosphors can provide red and green light, while blue light can be provided directly from the LED die. In this manner, any desired combination of red, green, and blue light can be provided. At least some such combinations can be perceived as being substantially white.

Any desire pattern of phosphors and/or vias can be used. For example, square, rectangular, round, oval, or triangular patterns of phosphors and/or vias can be used. The individual dots (such as squares 15 and 16 of FIG. 7) can similarly be of any desired shape.

According to an example of an embodiment, phosphors of one type will not substantially overlap phosphors of another type. In this manner, undesirable cannibalism of light emitted by phosphors is substantially mitigated.

A diffusant can be added to the layer furthest from the LED die, such as clear layer 11, 21, 31. The diffusant can scatter and mix the light emerging from the phosphors. Such scattering and mixing can mitigate the undesirable resolution of individual colors by subsequent imaging lenses. Such diffusants are well known in LED construction and are known to those skilled in the art.

As can be seen in FIGS. 1, 4, and 5, the phosphors 15 and 16 do not substantially overlap one another. Thus, light emitted by phosphor 16 does not tend to be substantially absorbed by the other phosphor 15. In this manner, light from both phosphors 15 and 16 is available for the desire application.

FIG. 8 is a semi-schematic cross-sectional view showing an LED assembly. The LED assembly can comprise an LED die and phosphor layer assembly 10, 20, 30. The LED die 81 can be mounted to a substrate 82. The phosphor layer assembly 10, 20, 30 can be disposed above the LED die 81 such that light from the LED die 81 passes through the phosphor layer assembly 10, 20, 30. Reflective walls 83 can reflect light that is directed away from the phosphor layer 10, 20, 30 back toward the phosphor layer 10, 20, 30.

The substrate 82 and the walls 83 can be part of a package for the LED die 81. The substrate 82 and the walls 83 can be part of an apparatus, such as a flashlight or general lighting fixture.

A Bragg mirror 86 can be formed upon the closest surface of any desired layer, e.g., a clear layer, to the LED die 81. For example, clear layer 14, 25, 34 can comprise a Bragg mirror. As those skilled in the art will appreciate, a Bragg mirror can comprise plural layers of dielectric material that are configured to reflect selected wavelengths of light. In this manner, the color of light incident upon the phosphors can be better controlled.

Also, light from within a phosphor layer 10, 20, 30 that is moving in a direction such that it will not be emitted by the LED assembly can be re-directed (reflected) by one of the Bragg mirrors such that it is emitted by the LED assembly and therefor contributes to the brightness of the LED asssembly. For example, light reflected from a phosphor or other item and that is moving back toward the LED die 81 can be reflected by a Bragg mirror, such as Bragg mirror 86 formed on the bottom of phosphor layer 10, 20, 30 so as to move once again away from LED die 81.

Referring now to FIG. 9, a block diagram shows the cannibalization of light from one phosphor 92 by another phosphor 94, according to contemporary practice. Light 91 emitted by LED die 81 is incident upon a phosphor 92. This phosphor 92 emits re-radiated light 93, which is typically of a different color with respect to light 91 from the LED die 81. In this instance, as is common according to contemporary practice, the re-radiated light 93 is absorbed by another phosphor 94. Such light 93 that is absorbed by another phosphor 94 tends to be absorbed thereby without re-emission and is thus wasted.

Thus, the other phosphor 94 cannibalizes light from phosphor 92. That is, light directly from phosphor 92 is not available for use because it is absorbed by phosphor 94. Of course, such cannibalization is wasteful. Such cannibalization undesirably reduces the brightness and efficiency of the LED assembly.

Referring now to FIG. 10 is a block diagram showing how non-overlapping phosphors 102 and 105 mitigate cannibalization of light, according to an example of an embodiment. Phosphors 102 and 105 do not substantially overlap one another. That is, one phosphor is not positioned such that it absorbs a substantial amount of light emitted by the other phosphor. Both phosphors 102 and 106 tend to absorb light from the LED die 81, rather than from the other phosphor 102, 106.

Light 101 emitted by LED die 81 is incident upon a phosphor 102. This phosphor 102 emits re-radiated light 103, which is typically of a different color with respect to light 101 from the LED die 81.

In a similar fashion light 104 emitted by LED die 81 is incident upon a different phosphor 105. This other phosphor 105 emits re-radiated light 106, which again is typically of a different color with respect to light 104 from the LED die 81.

Thus, the other phosphor 105 does not cannibalize light from phosphor 102. That is, light from both phosphors 102 and 105 is available for use because it has not been absorbed by phosphor 94. In this manner, wasteful cannibalization is mitigated. By mitigating cannibalization the brightness and efficiency of the LEDs is enhanced. Enhancing the brightness and efficiency of LEDs makes them more useful in a wider range of applications.

Further, by mitigating cannibalization better control of the color of light can be achieved. Better control of the color of light provided by LEDs can again make them more useful in a wider range of applications.

Any desired number of different phosphors or layers of phosphors can be used. Various different colors of light can be produced by different phosphors and different combinations of phosphors.

As used herein “formed upon” can be defined to include deposited, etched, attached, or otherwise prepared or fabricated upon when referring to the forming the various layers.

As used herein “on” and “upon” can be defined to include positioned directly or indirectly on or above.

As used herein, the term “package” can be defined to include an assembly of elements that houses one or more LED chips and provides an interface between the LED chip(s) and a power source to the LED chip(s). A package can also provide optical elements for the purpose of directing light generated by the LED chip. Examples of optical elements are lens and reflectors.

As used herein, the terms “clear” and “transparent” can be defined to include the characterization that no significant obstruction or absorption of electromagnetic radiation occurs at the particular wavelength or wavelengths of interest.

As used herein, the term “dot” can refer to a structure that is either round or not round. For example, such dots can be square, rectangular, triangular, round, oval, or of any other desired shape.

One or more embodiments facilitate the use of LEDs in applications where white light is desired, such as flashlights, displays, and area lighting. Such LEDs can generally provide light at a lower cost than other illumination devices, such as incandescent lights and fluorescent lights.

One or more embodiments facilitated the enhance control of the color provided by LED assemblies. Thus, desired combinations of colors, such as red, blue, and green, can be used to provide desired composite colors.

According to one or more embodiments, the undesirable cannibalization of light by phosphors is mitigated. Mitigating the cannibalization of light enhances both the efficiency and brightness of LED assemblies. Mitigating the cannibalization of light can also facilitate better control of the color of light emitted by an LED assembly.

Embodiments described above illustrate, but do not limit, the invention. It should also be understood that numerous modifications and variations are possible in accordance with the principles of the present invention. Accordingly, the scope of the invention is defined only by the following claims.

1. An LED assembly comprising a plurality of different types of phosphors that are separated from one another in a manner that substantially mitigates cannibalization of light emitted by at least one of the types of phosphors.

2. A phosphor layer for an LED assembly comprising a plurality of different types of phosphors wherein the phosphors define adjacent dots that are configured so as to substantially inhibit phosphor absorption/emission band interaction.

3. An LED assembly comprising:
an LED die;
a first layer comprising a first phosphor;
a second layer comprising a second phosphor;
wherein the first phosphor and the second phosphor receive light from the die and the first phosphor and the second phosphor each emit a different color of light with respect to one another; and
wherein the first phosphor and the second phosphor are arranged such that absorption of light by one that was emitted by the other is mitigated.

4. The LED assembly as recited in claim 3, wherein the first and second phosphors do not substantially overlap one another.

5. The LED assembly as recited in claim 3, wherein the first and second phosphors define a checkerboard pattern.

6. The LED assembly as recited in claim 3, wherein the first and second phosphors define a striped pattern.

7. The LED assembly as recited in claim 3, further comprising a plurality of vias configured so as to facilitate leakage of light from the LED die past the first phosphor and the second phosphor.

8. The LED assembly as recited in claim 3, further comprising a plurality of generally round vias configured so as to facilitate leakage of light from the LED die past the first phosphor and the second phosphor.

9. The LED assembly as recited in claim 3, further comprising a plurality of generally square vias configured so as to facilitate leakage of light from the LED die past the first phosphor and the second phosphor.

10. The LED assembly as recited in claim 3, further comprising a clear layer disposed between the first and second layers.

11. The LED assembly as recited in claim 3, further comprising a clear layer disposed between the first and second layers, the clear layer facilitating adhesion of the first and second layers.

12. The LED assembly as recited in claim 3, further comprising a clear layer covering the first and second layers.

13. The LED assembly as recited in claim 3, further comprising a clear layer intermediate the first and second layers and a plurality of vias formed through the first layer, the second layer, and the clear layer.

14. The LED assembly as recited in claim 3, further comprising:
a clear layer; and
a Bragg mirror formed upon the clear layer.

15. The LED assembly as recited in claim 3, further comprising:
a clear layer covering at least one of the first and second layers; and
a Bragg mirror formed upon a surface of the clear layer that is closest to the die.

16. An illumination assembly comprising:
a source of light;
a first phosphor layer comprising a first phosphor that is configured to change a color of light from the source to a first color;
a second phosphor layer comprising a second phosphor that is configured to change a color of light from the source to a second color; and
wherein the first and second phosphors are configures such that light emitted by one is not substantially absorbed by the other.

17. A method for modifying the color of light, the method comprising providing the light to a plurality of different types of phosphors that are separated from one another in a manner that substantially mitigates cannibalization of light emitted by at least one of the types of phosphors.

18. A method for modifying the color of light, the method comprising depositing a plurality of different types of phosphors as adjacent dots that substantially inhibit phosphor absorption/emission band interaction.

19. The method as recited in claim 18, wherein the dots do not substantially overlap one another.

20. The method as recited in claim 18, further comprising forming at least one via for facilitating leakage of light past the phosphors.
